(19) United States
(12) Patent Application Publication
(10) Pub. No.: US 2012/0048334 A1
(43) Pub. Date: Mar. 1, 2012

(54) PHOTOVOLTAIC MODULE COVER

(76) Inventors: Brian E. Cohen, Perrysburg, OH (US); Richard S. Malik, JR., Rossford, OH (US)

(21) Appl. No.: 13/220,804

(22) Filed: Aug. 30, 2011

Related U.S. Application Data
(60) Provisional application No. 61/378,254, filed on Aug. 30, 2010.

(51) Int. Cl. H01L 31/05; H01L 31/18

(52) U.S. Cl. 136/244; 438/57; 438/98; 257/E31.11; 257/E31.124

(57) ABSTRACT

Photovoltaic modules can include a dual opening substrate to improve, for example, safety, durability, and voltage handling capability.

### CLAIM OF PRIORITY

This application claims priority under 35 U.S.C. §119(e) to U.S. Provisional Patent Application Ser. No. 61/378,254 filed Aug. 30, 2010, which is hereby incorporated by reference in its entirety.

### TECHNICAL FIELD

The present invention relates to photovoltaic modules with dual opening substrates and methods of manufacturing photovoltaic modules with dual opening substrates.

### BACKGROUND

A photovoltaic module converts solar radiation into electricity. The conversion of photons to electricity occurs within a plurality of layers that are disposed between a transparent front superstrate and a protective back substrate. Strips of conductive tape serve as electrical leads and extend from the plurality of layers to an outer surface of the module where they connect to a junction box. While existing modules operate at or below 1000 volts, future modules may operate at higher voltage capacities. Modules operating at higher voltage capacities may require design changes to ensure safety and reliability.

### DESCRIPTION OF DRAWINGS

FIG. 1 is an exploded view of a photovoltaic module with a dual opening substrate.

FIG. 2 is a perspective view of a photovoltaic module with a dual opening substrate.

FIG. 3 is a perspective view of a photovoltaic module with a dual opening substrate.

FIG. 4 is a cross-sectional side view of a photovoltaic module with a dual opening substrate.

FIG. 5 is a cross-sectional side view of a photovoltaic module with a dual opening substrate.

FIG. 6 is a cross-sectional side view of a photovoltaic module with a dual opening substrate.

FIG. 7 is a perspective view of a photovoltaic module with a single opening substrate.

FIG. 8 is a cross-sectional side view of a photovoltaic module with a single opening substrate.

FIG. 9 is a cross-sectional side view of a photovoltaic module with a single opening substrate.

FIG. 10 is a cross-sectional side view of a photovoltaic module with a single opening substrate.

FIG. 11 is a side view of a tape dispenser.

FIG. 12 is a side view of a tape dispenser.

FIG. 13 is a cross-sectional side view of a photovoltaic module.

FIG. 14 is a flow chart of a method for preparing a substrate for a photovoltaic module.

FIG. 15 is a flow chart of a method for manufacturing a photovoltaic module.

FIG. 16 is a flow chart of a method for generating electricity.

FIG. 17 is an exploded view of a photovoltaic module with a dual opening substrate.

FIG. 18 is an exploded view of a photovoltaic module with a dual opening substrate.

FIG. 19 is a perspective view of a photovoltaic module with a dual opening substrate

FIG. 20 is a cross-sectional side view of a photovoltaic module with a dual opening substrate.

FIG. 21 is a cross-sectional side view of a photovoltaic module with a dual opening substrate.

### DETAILED DESCRIPTION

A photovoltaic module may contain a plurality of layers disposed between a superstrate layer and a substrate layer. The superstrate layer may be an optically transparent front cover and the substrate layer may be a protective back cover. Each layer can cover all or a portion of a photovoltaic device within the module and/or all or a portion of the layer or substrate underlying the layer. For example, a “layer” can include any amount of any material that contacts all or a portion of a surface. The plurality of layers, which convert photons to electricity, may include a transparent conductive oxide layer, two semiconductor layers, and a back contact layer. The transparent conductive oxide layer may be formed adjacent to the front substrate. The two semiconductor layers, which form a p-n junction, may be formed adjacent to the transparent conductive oxide layer. The back contact layer may be formed adjacent to the semiconductor layers. Finally, the protective back substrate may be placed adjacent to the back contact layer to complete the photovoltaic module.

The back contact layer may include a series of widely spaced thin metal strips. The thin metal strips may transport electrical current from the semiconductor layers to a thin metal bus bar. The bus bar may be a flexible conductive tape disposed between the back contact layer and the substrate. The conductive tape may serve as a flexible bus bar and may interconnect cells within the thin film photovoltaic module. The purpose of the conductive tape is to provide an electrical path for current to travel from the back contact layer to a junction box on an outer surface of the module. The conductive tape may include any suitable conductor. For example, the conductive tape may be a foil tape having a tin-plated copper foil backing to ensure excellent conductivity and corrosion resistance.

In previous modules, a hole was drilled though the substrate to create an access opening for the conductive tape to pass through. In this way, a first and second lead could be connected to a junction box mounted on the outer surface of the module. The first and second leads were then pulled taught against opposing sides of the access opening, thereby ensuring no physical contact between them. This configuration was suitable for modules operating at 1000V and below. However, for modules operating at higher voltages, a new substrate design is needed that ensures safety, reliability, and longevity of the module. It is also desirable for the new design to make use of existing manufacturing methods and tooling.

In one aspect, a photovoltaic module can include a substrate, which can include a top surface, a bottom surface opposite the top surface, a first opening extending from the top surface to the bottom surface, and a second opening extending from the top surface to the bottom surface. The photovoltaic module can include a plurality of layers adjacent to the substrate layer. The photovoltaic module can include a first conductive tape disposed between the substrate layer and the plurality of layers. The first conductive tape can extend through the first opening to form a first lead. The photovoltaic module can include a second conductive tape disposed between the substrate layer and the plurality of layers. The second conductive tape can extend through the second opening to form a second lead.

The diameter of the first opening can be about 10 mm to about 40 mm. The diameter of the second opening can be about 10 mm to about 40 mm. The diameter of the first opening can be about 15 mm to about 25 mm. The diameter of the second opening can be about 15 mm to about 25 mm. The separation distance between the first lead and the second lead can be greater than or equal to about 25 mm. The openings can be substantially centered between a first short end and a second short end of the substrate. The openings can be formed closer to the first short end than the second short end of the substrate. The openings can be substantially centered between a first long end and a second long end of the substrate. The openings can be formed closer to the first long end than the second long end of the substrate.

The first conductive tape can be pressure-sensitive adhesive foil tape, and the second conductive tape can be pressure-sensitive adhesive foil tape. The plurality of layers can include a back contact layer. The back contact layer can include a metal. The plurality of layers can include a semiconductor absorber layer. The absorber layer can include a p-type semiconductor layer. The p-type semiconductor layer can include cadmium telluride. The plurality of layers can include a semiconductor window layer. The semiconductor window layer can include a n-type semiconductor layer adjacent to the semiconductor absorber layer. The n-type semiconductor layer can include cadmium sulfide. The plurality of layers can include a transparent conductive oxide layer. The transparent conductive oxide layer can include cadmium stannate. The photovoltaic module can include a superstrate layer adjacent to the plurality of layers. The substrate layer can include soda-lime glass.

In another aspect, a method for preparing a substrate layer for a photovoltaic module can include providing a substrate layer comprising a top surface and a bottom surface opposite the top surface. The method can include providing a first opening extending from the top surface to the bottom surface and a second opening extending from the top surface to the bottom surface. The distance from a center of the first opening to a center of the second opening can be greater than about 20 mm.

In another aspect, a method for manufacturing a photovoltaic module can include providing a superstrate layer and forming a plurality of layers adjacent to the superstrate layer. The method can include laying a strip of conductive tape adjacent to the plurality of layers. The strip of conductive tape can include a first loop and a second loop. The method can include forming a substrate layer adjacent to the plurality of layers. The substrate layer can include a top surface, a bottom surface opposite the top surface, a first opening extending from the top surface to the bottom surface, and a second opening extending from the top surface to the bottom surface. The first loop can extend through the first opening and the second loop can extend through the second opening. The method can include cutting the strip of conductive tape at the first loop to form a first lead. The method can include cutting the strip of conductive tape at the second loop to form a second lead. The method can include attaching a junction box adjacent to the first lead and the second lead.

In another aspect, a method for generating electricity can include illuminating a photovoltaic module with light to generate photocurrent and collecting the photocurrent. The photovoltaic module can include a substrate layer. The substrate layer can include a top surface, a bottom surface opposite the top surface, a first opening extending from the top surface to the bottom surface, and a second opening extending from the top surface to the bottom surface. The photovoltaic module can include a plurality of layers adjacent to the substrate layer. The photovoltaic module can include a first conductive tape disposed between the substrate layer and the plurality of layers. The first conductive tape can extend through the first opening to form a first lead. The photovoltaic module can include a second conductive tape disposed between the substrate layer and the plurality of layers. The second conductive tape can extend through the second opening to form a second lead.

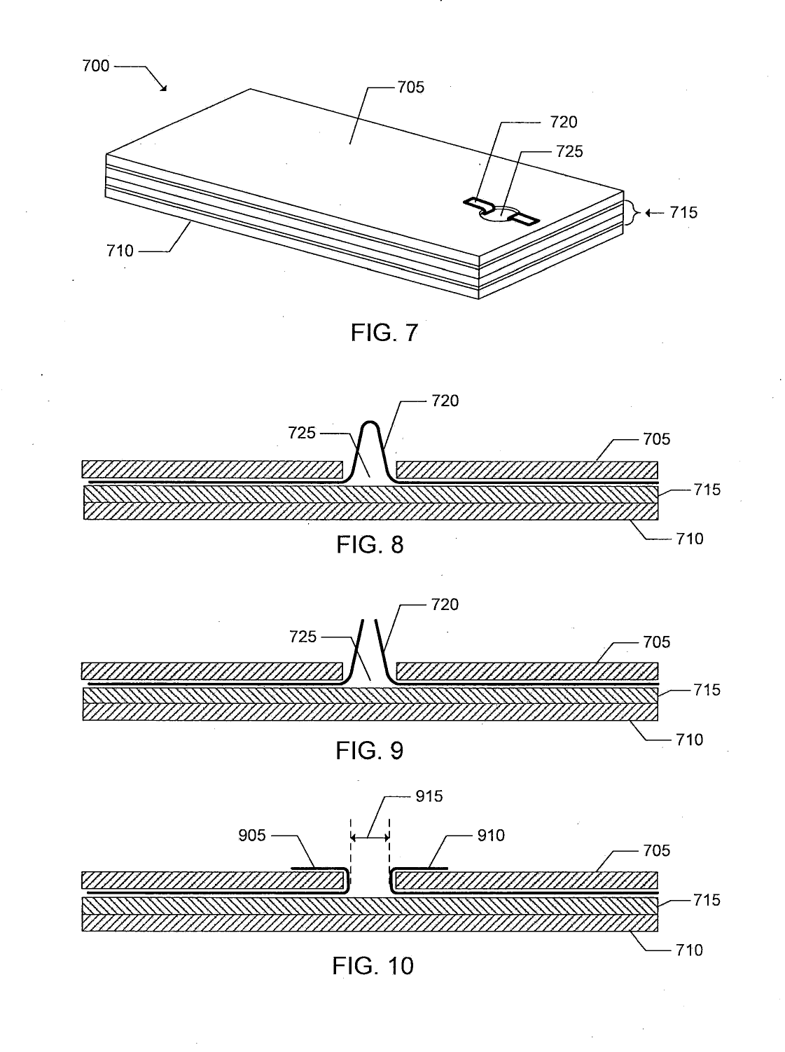

FIGS. 7-10 show a known method for forming conductive tape 720 for a photovoltaic module 700. FIG. 7 shows a perspective view of the module 700 where the method is complete, and FIGS. 8-10 show forming, cutting, and folding steps, respectively. In FIG. 8, the conductive tape 720 is formed between a plurality of layers 715 and a substrate layer 705. A single loop of conductive tape 720 is formed and inserted through a opening 725 in the substrate layer 705. For example, the loop may be created when the conductive tape 720 is spooled onto the plurality of layers 715. Then, the substrate layer 705 may be positioned on the plurality of layers 715 such that the loop of conductive tape 720 protrudes through the opening 725 in the substrate layer 705. Once the loop is through the substrate 705, it may be cut near the peak of the loop as shown in FIG. 8. By cutting the loop, a first lead 905 and a second lead 910 are formed. The first and second leads (905, 910) may then be folded back against a surface of the substrate layer 705 as shown in FIG. 9, where the first and second leads (905, 910) can be connected to a junction box.

The known method, which is shown in FIGS. 7-10, is suitable for photovoltaic modules 700 operating at or below 1000 volts. However, for photovoltaic modules operating above 1000 volts, design changes are required to ensure safety and reliability of the module. For example, when operating at 1500 volts, greater care must be taken to segregate a positive lead from a negative lead. If the leads are too close to each other, electrons may migrate directly from the negative lead to the positive lead, thereby rendering the solar module ineffective and potentially dangerous. As shown in FIG. 10, the separation distance 915 between a first lead 905 and a second lead 910 is about equal to the diameter of the opening 725 in the substrate layer 705. The diameter of the opening 725 is about 22.5 mm inches in prior modules 700 and is suitable for voltages at or below 1000 volts. However, as voltages surpass 1000 volts, it is necessary to increase the separation distance between the first and second leads. It is also desirable to develop a method that makes use of current tooling and does not require additional manufacturing steps.

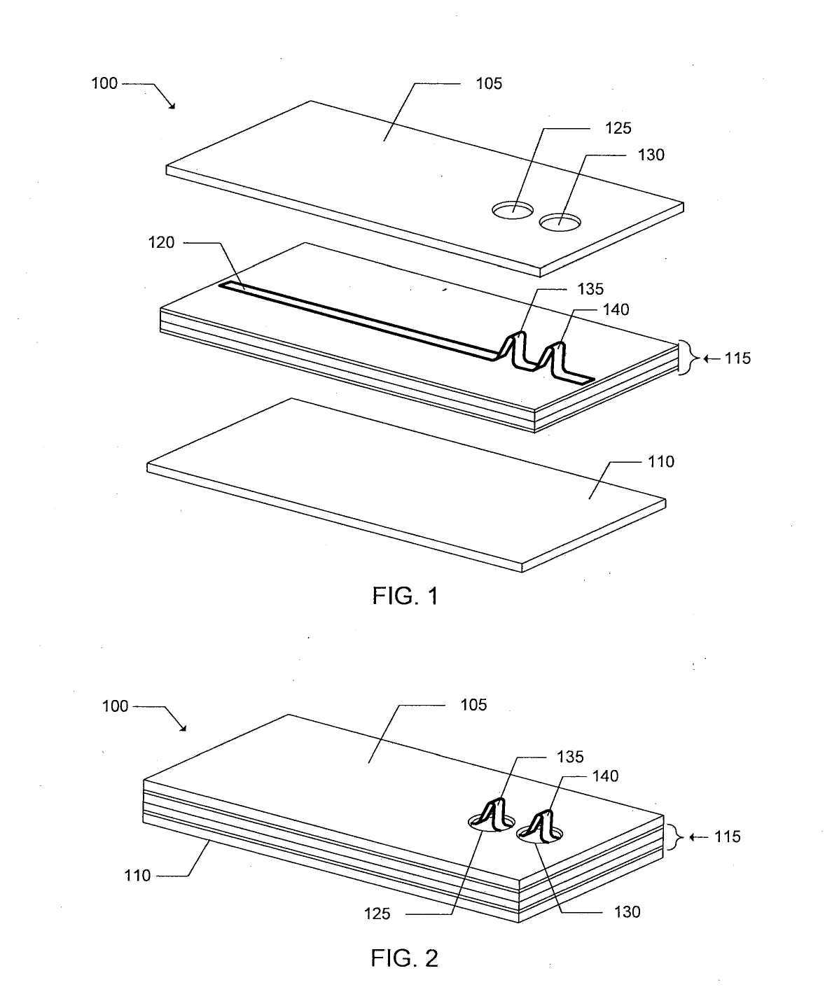

A new method for forming conductive tape within a photovoltaic module 100 is shown in FIGS. 1-6. FIGS. 1-3 show perspective views of successive steps of forming conductive tape 120 between a substrate layer 105 and a plurality of layers 115. In particular, FIG. 1 shows an exploded view of a substrate layer 105, a plurality of layers 115, a superstrate layer 110, and a strip of conductive tape 120. Plurality of layers 115 can include any suitable layers formed in any suitable manner. For example, one or more layers can be deposited on superstrate 110 by any suitable method. A barrier layer can be formed immediately adjacent to superstrate 110. A TCO layer can be formed adjacent to the barrier layer. The TCO layer can be include any suitable material; such as cadmium, tin, and or oxygen. The TCO layer can include cadmium stannate. The TCO layer can include tin oxide. A buffer layer can be formed adjacent to the TCO layer.

Whether or not the plurality of layers 115 includes a buffer layer, a semiconductor window layer can be formed adjacent to the TCO layer. The semiconductor window layer can include any suitable material. The semiconductor window layer can include cadmium sulfide. A semiconductor absorber layer can be formed adjacent to the semiconductor window layer. The semiconductor absorber layer can include any suitable material, such as cadmium telluride. A back contact layer (which can include any suitable material, for example, a metal) can be formed adjacent to the semiconductor absorber layer.

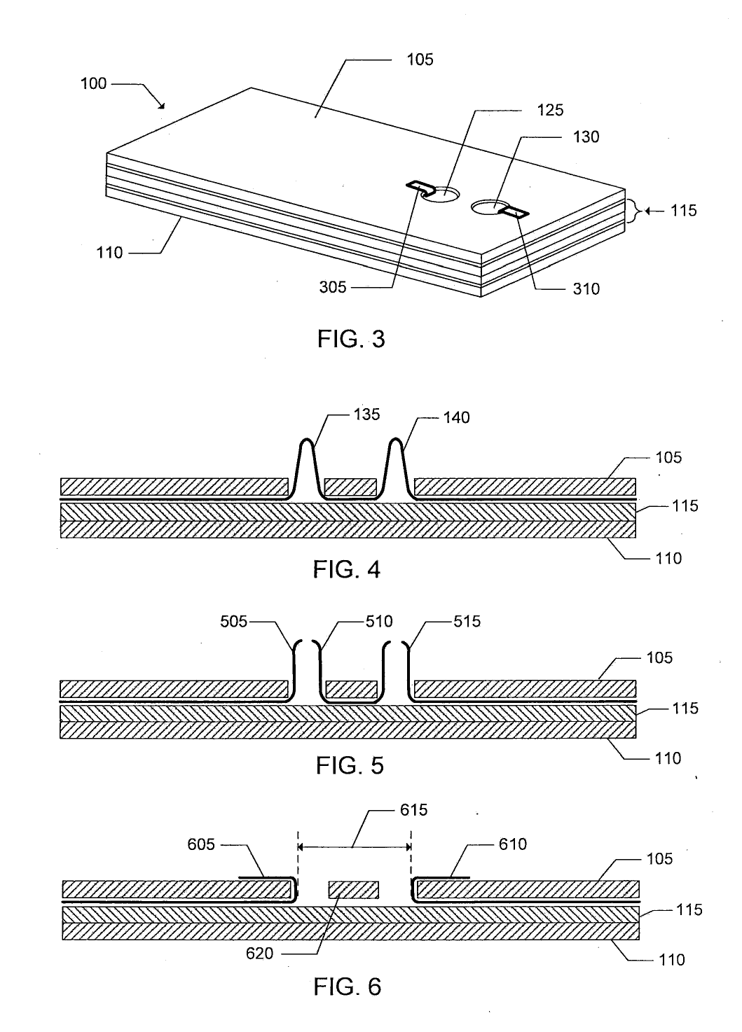

As shown in FIG. 2, the superstrate layer 110, which may be formed from soda lime glass, may be placed adjacent to the plurality of layers 115 to form an optically transparent front cover for the module 100. Similarly, a substrate layer 105 may be placed adjacent to the opposite side of the plurality of layers 115. The substrate layer 105 may contain a first opening 125 and a second opening 130 to accommodate a first loop 135 and a second loop 140 of conductive tape 120. As shown in FIG. 2, when the substrate 105 is added to the module 100, the first and second loops (135, 140) of conductive tape 120 may extend through the first and second openings (125, 130). Subsequently, the first and second loops (135, 140) may be cut near their peaks, and the resulting ends may be folded back against a surface of the substrate 105 as shown in FIG. 3. As a result of the cutting and folding steps, a first lead 305 and a second lead 310 are formed adjacent to the substrate layer 105.

FIGS. 4-6 show a side cross-sectional view of the forming, cutting, and folding steps, respectively. In particular, FIG. 4 show the first loop 135 and the second loop 140 formed between the plurality of layers 115 and the substrate layer 105. Once the substrate layer 105 is secured, the first and second loops (135, 140) may be cut as shown in FIG. 5. The two cuts result in the conductive tape being divided into three pieces. The first piece 505 and the third piece 515 serve as a first lead 605 and a second lead 610, while the second piece 510 in the middle serves no function and can be removed and discarded. As shown in FIG. 6, the first and second leads (605, 610) may be folded back against the surface of the substrate layer 105 where they may be connected to a junction box.

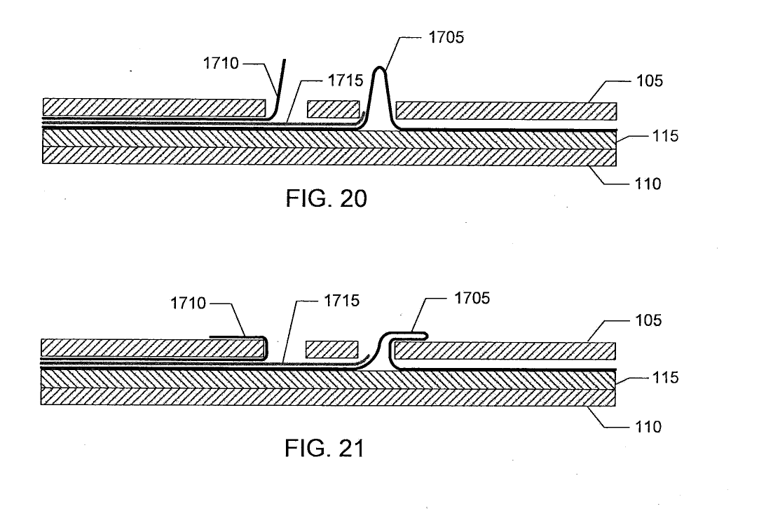

FIGS. 17-21 show an alternate method for forming a first and second conductive lead adjacent to a dual opening substrate 105. For example, a first conductive lead 1705 may be formed adjacent to the plurality of layers 115. An insulating layer 1715 may be formed adjacent to the first lead 1705, and the second lead 1710 may be formed adjacent to the insulating layer 1715. The insulating layer 1715 may serve as an insulating barrier between the first and second leads (1705, 1710), thereby avoiding short circuiting. The insulating layer 1715 may be formed from any suitable insulating material and may be coated with adhesive to ensure stable positioning between the first and second leads (1705, 1705). For instance, the insulating layer 1715 may be a double-sided tape or a pressure sensitive adhesive tape.

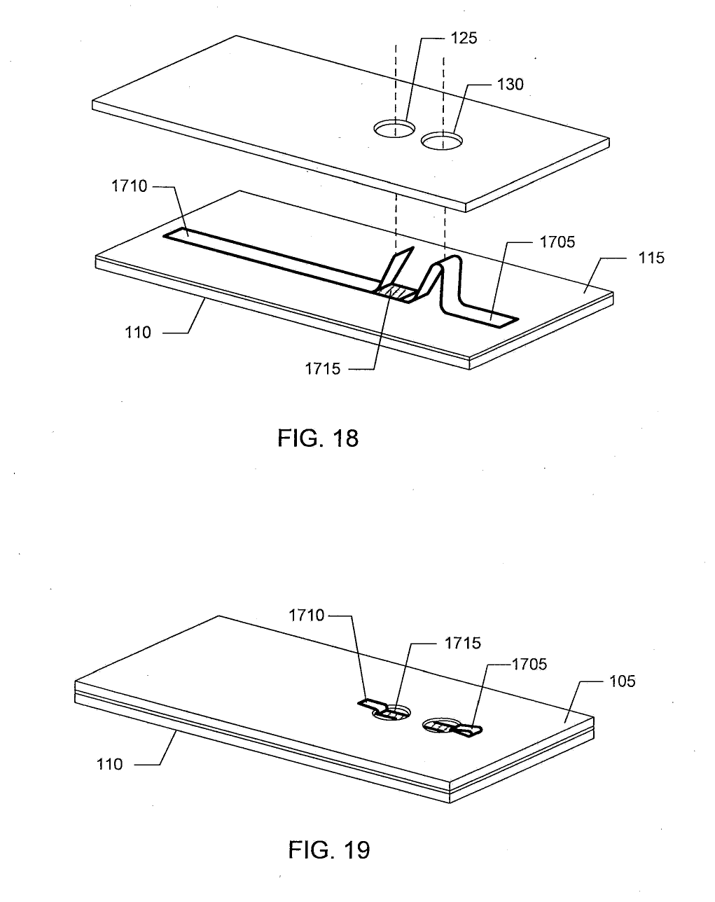

During manufacturing, the dual opening substrate 105 may be placed over the leads as shown in FIGS. 18-21. The first lead 1705 may be inserted through the first opening 125 and the second lead 1710 may be inserted through the second opening 130. The first lead 1705 may be folded back against the top surface of the substrate layer 105 as shown in FIG. 21. Similarly, the second lead 1710 may be folded back against the top surface of the substrate layer 105. A junction box may then be placed over the first and second leads (1705, 1710), thereby facilitating electrical connection to other electrical components.

The dual opening design results in a larger separation distance 615 between the first and second leads (605, 610) as shown in FIG. 6. Creating a larger separation distance 615 reduces the possibility of electrons migrating directly between the first lead 605 and the second lead 610 lead during high-voltage operation. The new design also results in the leads being physically separated by an insulating portion 620. This increases safety of the module by reducing the likelihood of short circuiting if a lead becomes detached from the surface of the substrate layer 105. To further enhance safety and durability of the module, a potting material may be added to the first and second openings (125, 130). In addition to providing electrical insulation between the first and second leads, the potting material may also provide a moisture barrier which protects the plurality of layers 115 from moisture ingress. The potting material may include any suitable potting material or compound.

To take advantage of existing tooling, the first and second openings (125, 130) may have diameters ranging from about 10 mm to about 40 mm. More preferably, the first and second openings (125, 130) may have diameters ranging from about 15 mm to about 25 mm. The separation distance 615 between the first and second leads (605, 610) is controlled by the distance between the center of the first opening 125 and the center of the second opening 130. The proper separation distance 615 may be selected based on the voltage capacity of the photovoltaic module 100. For example, the separation distance 615 may increase as the voltage capacity of the module 100 increases. For modules operating at 1500 volts, the separation distance 615 may be greater than or equal to about 20 mm. More preferably, the separation distance 615 may be greater than or equal to about 25 mm.

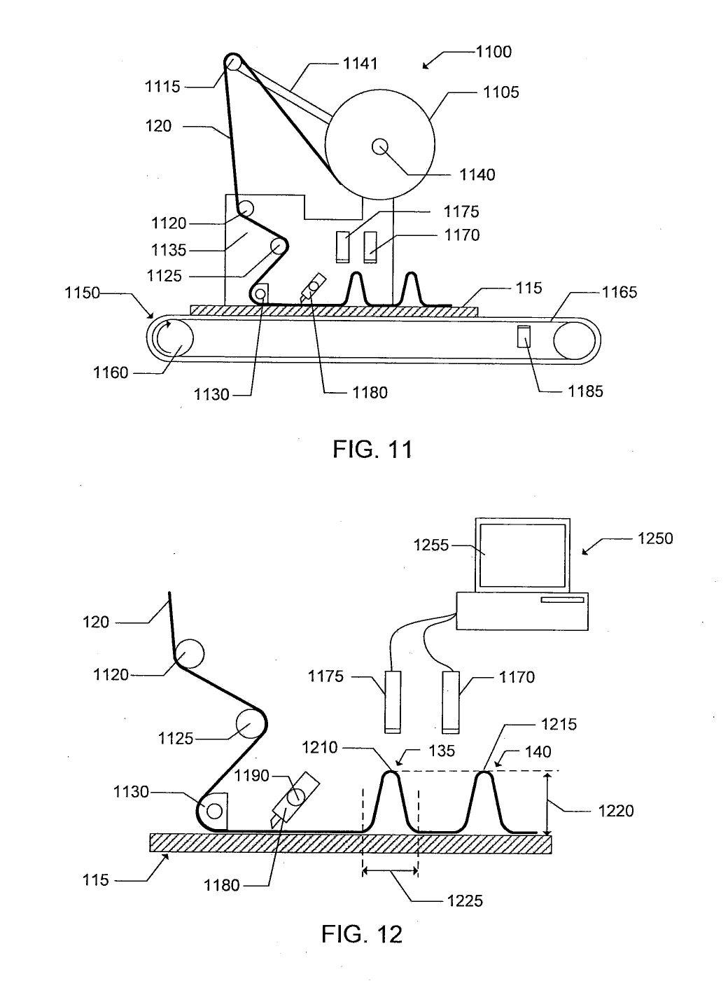

While the conductive tape 120 may be formed adjacent to the substrate layer 105 by hand, it is more efficient to use a tape dispenser 1100 as shown in FIG. 11. A tape dispenser 1100 may be configured to dispense conductive tape 120 onto a plurality of layers 115 of a photovoltaic module 100. For instance, the conductive tape 120 may be wound around a cylinder to form a spool 1105 of conductive tape 120. The spool 1105 may be attached to a body 1135 of the tape dispenser 1100 by a hub 1140 capable of rotating. The conductive tape 120 may be routed through several rollers (e.g. 1115, 1120, 1125) and a tape head 1130 before being dispensed onto the plurality of layers 115. The tape head 1130 may include a spring member that creates downward force against the plurality of layers 115, thereby ensuring uniform application of the conductive tape 120.

As noted above, the tape dispenser 1100 may include a plurality of rollers (e.g. 1115, 1120, 1125). The rollers may guide the conductive tape 120 from the spool 1105 to the tape head 1130. To ensure the conductive tape 120 does not deviate laterally from its target dispensing location, the rollers (e.g. 1115, 1120, 1125) may have uniform diameters. For example, each roller may have the same, or nearly the same, diameter as the other rollers. The diameters of the rollers may range from 2 mm to 20 mm. More preferably, the diameter of the rollers may range from 4 mm to 10 mm. By incorporating rollers having equal diameters, alignment of the conductive tape 120 may be improved. In turn, product quality may be improved, and the dispensing rate may be increased.

The tape machine 1100 may contain driven rollers and non-driven rollers. The driven rollers may receive a torque input from an electric motor or pulley, whereas the non-driven rollers do not. A first roller 1115 and a second roller 1120 may be non-driven rollers and may rotate freely. A third roller 1125 may be a driven roller capable of drawing the conductive tape 120 from the spool 1105. The outer surfaces of the non-driven rollers (e.g. 1115, 1120) may be smooth to avoid damaging the conductive tape, whereas the surface of the driven roller (e.g. 1125) may include a high friction material, such as a rubber compound, to grip the tape 120.

The tape dispenser 1100 may be positioned near, or connected to, a conveyor system 1150. The conveyor system 1150 may include a conveyor surface 1165 and a drive mechanism 1160 for propelling the conveyor surface 1165. The drive mechanism 1160 may include, for example, an electric motor and gear assembly capable of transmitting motion to the conveyor surface 1165. The conveyor surface 1165 may include a belt, roller, cart, trolley, chain, or screw to move the partially completed module 100 over a fixed path. Alternately, any other suitable conveyor surface may be used. A conveyor speed sensor 1185 may monitor the speed of the conveyor surface 1165. During manufacturing, the plurality of layers 115 may be loaded onto the conveyor surface 1165, and the drive mechanism 1160 may be activated. The drive mechanism may cause the conveyor surface 1165 to move at a uniform rate in a linear direction. The plurality of layers 115 may ride on the conveyor surface 1165 and pass beneath the tape head 1130. The tape head 1130 may dispense a strip of conductive tape onto the surface of the plurality of layers 115.

To facilitate assembly of the photovoltaic module 100, it may be desirable to create the first loop 135 and the second loop 140 on the surface of the plurality of layers 115, as shown in FIG. 12. The first and second loops (135, 140) may be created by setting the dispensing rate higher than the conveyor rate. As a result, an excess of conductive tape 120 may be created on the surface of the plurality of layers 115. The first and second loops (135, 140) may project upwardly from the surface of the plurality of layers 115 and have peaks (1210, 1215). The peaks (1210, 1215) may be the portions of dispensed tape 120 farthest from the surface of the plurality of layers 115. Loop height 1220 is a distance measured from the surface of the plurality of layers 115 to the peaks (1210, 1215) of the loops (135, 140) and is measured in a direction normal to the surface of the plurality of layers 115. Loop width 1225 is a distance measured between the flats one either side of the loop. During assembly of the photovoltaic module 100, the first loop 135 may be fed through a the first opening 125 in the substrate layer 105, as shown in FIGS. 1-3. Similarly, the second loop 140 may be fed through a the second opening 130 in the substrate layer 105.

The rate at which the conductive tape 120 is dispensed may be monitored by a speed sensor 1175. The speed sensor 1175 may be mounted to the body 1135 of the tape dispenser 1100. The speed sensor 1175 may monitor the dispensing rate by monitoring the linear speed of the tape 120 as it passes the sensor. Alternately, the speed sensor 1175 may monitor the rotational speed of one of the rollers (e.g. 1115, 1120, 1125). By multiplying the rotational speed of the roller by the circumference of the roller, the dispensing speed can be calculated. To facilitate real-time calculation and monitoring of the dispensing rate, the speed sensor 1175 may be connected to a computer 1250, as shown in FIG. 12.

The loop height 1220 may be critical to proper assembly of the photovoltaic module 100. For instance, to facilitate assembly, the loop height 1220 may need to remain within a range of 5 mm to 30 mm. To ensure proper loop height 1220, feedback may be incorporated into the tape dispenser 1100. For instance, a height sensor 1170 may measure the loop height 1220 during dispensing. The information acquired from the height sensor 1170 may be input into the computer 1250 and used to increase or decrease the dispensing rate. For example, if the loop height 1220 is less than the target loop height, the dispensing rate may be increased. Conversely, if the loop height 1220 is greater than the target loop height, the dispensing rate may be reduced.

To ensure the conductive tape 120 is being dispensed in the correct position on the surface of the plurality of layers 115, the tape dispenser 1100 may include a vision system (not shown) which monitors the position of the tape in a direction normal to the direction of conveyor movement and normal to the direction of the loop height 1220. The vision system may include a Charge Coupled Device (CCD) camera and image processing software.

The speed sensor 1175, height sensor 1170, conveyor speed sensor 1185, and vision system may be connected to the computer 1250. The computer 1250 may be configured to receive and process signals. For instance, the computer 1250 may include a data acquisition board capable of converting analog signals received from the sensors into digital signals readable by the computer 1250. The computer 1250 may monitor, record, and store signal data in a database.

The computer 1250 may include a software program that permits execution of one or more manufacturing processes. For instance, the software may enable application of conductive tape 120 with little or no manual input. A user may place a partially completed photovoltaic module 100 onto the conveyor surface 1165 and initiate a program which automatically applies conductive tape 120 as described herein. The software program may enable display of a graphical user interface (GUI) on a monitor 1255 associated with the computer 1250. The graphical user interface may allow a user to input target manufacturing parameters such as conveyor speed, dispensing rate, and loop height 1220. The graphical user interface may display data acquired from the sensors (e.g. 1170, 1175, 1185) in real-time while manufacturing is in progress. In addition, the graphical user interface may allow the user to recall test data from the database and create, display, and print charts and graphs generated from the stored data.

The computer 1250 may continuously monitor signals and make adjustments to the manufacturing process based on those signals. For instance, the computer 1250 may receive and compare conveyor speed to dispensing rate. If the goal is to apply conductive tape 120 adjacent to the passing module 100, the dispensing rate and conveyor speed should be equal. But if signals received from the sensors (e.g. 1175, 1185) indicate that the speeds are not equal, the computer 1250 may adjust parameters to bring the process within conformance. For instance, based upon feedback received from the sensors, the computer 1250 may adjust the conveyor speed to match the dispensing rate. To accomplish this, the computer 1250 may calculate the conveyor speed based on a signal received from the conveyor speed sensor 1185. Also, the computer 1250 may calculate the dispensing rate based on a signal received from the tape speed sensor 1175. Next, the computer 1250 may compare the actual speeds to target speeds defined within the GUI or software code. If the speeds do not match, the computer 1250 may adjust the speeds accordingly. For example, if the tape dispensing rate is less than the target dispensing rate, the computer 1250 may increase the rotational rate of a driven roller (e.g. 1125). Similarly, if the conveyor speed is greater than the target conveyor speed, the computer 1250 may decrease the rotational rate of the drive mechanism 1160. To ensure adequate control, the computer 1250 may be configured to continuously compare actual parameters to target parameter during the manufacturing process. Alternately, the computer 1250 may be configured to compare parameters at predefined intervals. For instance, the computer may compare parameters every 10 milliseconds.

The computer 1250 control system described above may also allow the tape dispenser 1100 to dispense conductive tape 120 using dynamic dispensing rates. For example, the tape dispenser 1100 may apply conductive tape 120 to the surface of the plurality of layers 115 using dispensing rates which vary linearly or nonlinearly with time. As a result, the tape dispenser 1100 is capable of creating the first and second loops (135, 140) of conductive tape 120 as described above. As shown in FIGS. 11 and 12, the tape dispenser 1100 may dispense a section of flat tape, followed by a first loop 135, followed by another section of flat tape, followed by a second loop 140. Alternately, the tape dispenser 1100 may dispense any combination of flat and curved sections of tape 120.

To create the first loop 135 of conductive tape 120 shown in FIG. 12, the computer 1250 may adjust the dispensing rate in relation to the conveyor speed. A target loop height 1220 may be defined within the graphical user interface or within the software program. Based upon formulas within the software code, the computer 1250 may calculate the proper speed differentials required to create a desired loop height 1220 and loop length 1225. For example, the computer 1250 may increase the difference between the dispensing rate and the conveyor speed during creation of the first loop 135. The loop length 1225 of the first loop 135 may be controlled by adjusting the duration for which the dispensing rate is unequal to the conveyor rate. For example, to increase the loop length 1225 of the first loop 135, the dispensing rate may remain unequal to the conveyor rate for an increased duration. Once the first loop 135 is created, the computer 1250 may reduce the dispensing rate to match the conveyor rate. To further aid formation of the first loop 135, the tape head 1130 may rotate or move upwardly to enable dispensing of excess tape 120. In particular, during formation of the first loop 135, the tape head 1130 may not exert a downward force against the surface of the plurality of layers 115.

The tape dispenser 1100 may also include a cutting blade 1180, as shown in FIGS. 11 and 12. The cutting blade 1180 may be pivotally mounted to the body 1135 of the tape dispenser 1100. The cutting blade 1180 may be attached to a second hub 1190. By rotating the second hub 1190 in a counterclockwise direction, the cutting blade 1180 may be brought into contact with the conductive tape 120. If sufficient torque is applied to the second hub 1190, the cutting blade 1180 will shear the conducting tape 120. Alternately, the cutting blade 1180 may move linearly, in an up and down direction, to facilitate cutting. Alternately, any other suitable means of actuating the cutting blade 1180 may be employed. During the manufacturing process, the cutting blade 1180 may be activated after the proper amount of conductive tape 120 has been dispensed. For instance, based on input parameters, sensor signals, and software code, the computer 1220 may detect when the proper amount of conductive tape 120 has been dispensed. At this moment, the computer 1250 may actuate the cutting blade 1180, thereby severing the conducting tape 120.

Although the figures depict a fixed tape dispenser 1100 and a moving plurality of layers 115, this is not limiting. During manufacturing, the plurality of layers 115 may remain motionless while the tape dispenser 1100 moves relative to the plurality of layers 115. For example, the tape dispenser 1100 may be mounted on a rail system and have a drive system that allows the dispenser to move axially. As a result, the tape dispenser 1100 may traverse the plurality of layers 115 and apply conductive tape 120 similar to the methods described herein.

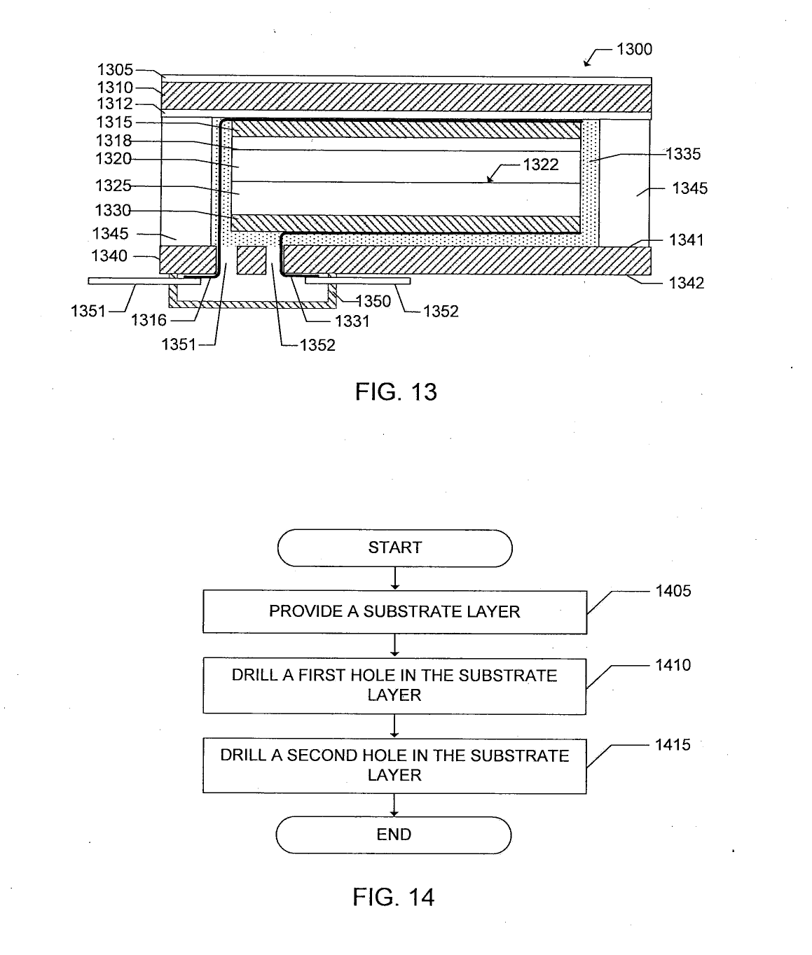

The photovoltaic module may be more elaborate than the modules described above. For example, as shown in FIG. 13, the photovoltaic module 1300 may contain an anti-reflective coating 1305 formed on the superstrate layer 1310. The anti-reflective coating 1305 may be designed to reduce reflection and increase transmission. For instance, reflections are minimized if the coating is approximately one-quarter-wavelength thick with respect to the wavelengths of incident photons. Since cadmium telluride may be used in the p-type semiconductor layer, which has a bandgap energy of 1.48 eV, the anti-reflective coating 1305 may have a thickness of about 0.15 microns. The anti-reflective coating 1305 may contain, for example, aluminum oxide, titanium dioxide, magnesium oxide, silicon monoxide, silicon dioxide, or tantalum pentoxide. Since the anti-reflective coating 1305 only optimizes transmission at a single wavelength, it may be desirable to modify the surface of the superstrate layer 1310 to improve overall transmission. For instance, the superstrate layer 1310 may be textured prior to adding the anti-reflective coating 1305 to enhance light trapping.

The superstrate layer 1310 may be formed from an optically transparent material such as soda-lime glass. Since quality and cleanliness of a glass superstrate layer can have a significant effect on performance of the module, polishing the glass with cerium oxide powder may be desirable to increase transmission. Adjacent to the superstrate layer 1310, a barrier layer 1312 may be formed to lessen diffusion of sodium or other contaminants from the superstrate layer 1310. The barrier layer 1312 may include silicon dioxide or any other suitable material.

A transparent conductive oxide layer 1315 may be formed between the barrier layer 1312 and a buffer layer 1318 and may serve as a front contact for the module 1300. In forming the TCO layer 1315, it is desirable to use a material that is both highly conductive and highly transparent. For example, the TCO layer 1315 may include tin oxide, cadmium stannate, or indium tin oxide. To further improve transparency, the TCO layer 1315 may be about 1 micron thick. If cadmium stannate is used, application of the cadmium stannate may be accomplished by mixing cadmium oxide with tin dioxide using a 2:1 ratio and depositing the mixture onto the superstrate layer 1310 using radio frequency magnetron sputtering. A buffer layer 1318 may be formed between the TCO layer 1315 and a n-type semiconductor layer 1320 to decrease the likelihood of irregularities occurring during formation of the re-type semiconductor layer.

The n-type semiconductor layer 1320 may include a very thin layer of cadmium sulfide. For instance, the n-type semiconductor layer 1320 may be 0.1 microns thick and may be deposited using any suitable thin-film deposition technique. For example, the n-type semiconductor layer 1320 may be deposited using a metal organic chemical vapor deposition (MOCVD). To reduce surface roughness of the n-type semiconductor layer 1320, it may be annealed at approximately 400 degrees Celsius for about 20 minutes. The annealing process may improve the boundary between the n-type semiconductor layer 1320 and the p-type semiconductor layer 1325 by reducing defects. As a result, the efficiency of the photovoltaic module may be improved.

The p-type semiconductor layer 1325 may be formed adjacent to the n-type semiconductor layer 1320 and may include cadmium telluride. The p-type semiconductor layer 1325 may be deposited using any suitable deposition method. For instance, the p-type semiconductor layer 1325 may be deposited using atmospheric pressure chemical vapor deposition (APCVD), sputtering, atomic layer epitaxy (ALE), laser ablation, physical vapor deposition (PVD), close-spaced sublimation (CSS), electrodeposition (ED), screen printing (SP), spray, or MOCVD. Following deposition, the p-type semiconductor layer 1325 may be heat treated at a temperature of about 420 degrees Celsius for about 20 minutes in the presence of cadmium chloride, thereby improving grain growth and reducing grain boundary trapping effects on minority carriers. By reducing trapping effects within the p-type semiconductor layer 1325, open-circuit voltage may be increased.

A p-n junction 1322 is formed where the p-type semiconductor layer 1325 meets the n-type semiconductor layer 1320. The p-n junction 1322 contains a depletion region characterized by a lack of electrons on the n-type side of the junction and a lack of holes (i.e. electron vacancies) on the p-type side of the junction. The width of the depletion region is equal to the sum of the diffusion depths located on the p-type side and the n-type side. The respective lack of electrons and holes is caused by electrons diffusing from the n-type semiconductor layer 1320 to the p-type semiconductor layer 1325 and holes diffusing from the p-type semiconductor layer 1325 to the n-type semiconductor layer 1320. As a result of the diffusion process, positive donor ions are formed on the n-type side and negative acceptor ions are formed on the p-type side. The positive donor ions may be phosphorous atoms locked in a silicon lattice that have donated an electron, and the negative acceptor ions may be boron atoms locked in a silicon lattice that have gained an electron. The presence of a negative ion region near a positive ion region establishes a built-in electric field across the p-n junction 1322. When the photovoltaic module 1300 is exposed to sunlight, photons are absorbed within the junction region. As a result, photo-generated electron-hole pairs are created. Movement of the electron-hole pairs is influenced by the built-in electric field, which produces current flow. The current may flow between a first lead 1316 formed adjacent to the TCO layer 1315 and a second lead 1331 formed adjacent to a back contact layer 1331.

The back contact layer 1330 may be formed adjacent to the p-type semiconductor layer 1325. The back contact layer 1330 may be a low-resistance ohmic contact that maintains good contact with the p-type semiconductor layer 1325 during temperature cycling. To ensure stability of the back contact layer 1330, a rear surface of the p-type semiconductor layer 1325 may be etched with nitric-phosphoric (NP) to create a layer of elemental tellurium on the rear surface, and the back contact layer 1330 may cover the entire back surface of the p-type semiconductor layer 1325. Alternately, as described above, the back contact layer 1330 may include a series of widely spaced thin metal strips. The thin metal strips may transport electrical current between the p-type semiconductor layer 1325 and the strip of conductive tape that functions as bus bars within the thin film module. The back contact layer 1330 may include aluminum applied through evaporation that is subsequently annealed. Alternately, the back contact 1330 may include molybdenum or any other suitable low-resistance material such as silver or gold.

A plurality of layers formed between the superstrate layer 1310 and substrate layer 1340 may be encapsulated by an interlayer 1335. For example, the interlayer 1335 may encapsulate the plurality of layers which includes the TCO layer 1315, the buffer layer 1318, the n-type semiconductor layer 1320, the p-type semiconductor layer 1325, and the back contact layer 1330. The interlayer 1335 may protect the plurality of layers from moisture and water ingress and may provide containment of materials if the photovoltaic module is physically damaged. The interlayer 1335 may include a polymer material such as, for example, ethylene-vinyl acetate (EVA), but any other suitable material may be used. To form the interlayer 1335, the plurality of layers may be laminated between two sheets of ethylene-vinyl acetate (EVA). As a result, the plurality of layers may be completely encapsulated within a watertight polymer casing. To further protect the module from moisture, an edge sealant 1345 may be added around the perimeter of the module and may included any suitable sealant such as butyl rubber.

The substrate layer 1340 may be formed adjacent to the interlayer 1335 and may further protect the back side of the module. The substrate layer 1340 may be constructed from soda-lime glass or any other suitable material. As described above, the substrate layer 1340 may have a first opening 1351 and a second opening 1352 which extend though the substrate 1340 from a top surface 1341 to a bottom surface 1342. A first lead 1316 may contact the TCO layer 1315 and may pass through the first opening 1351. A second lead 1331 may contact the back contact layer 1330 and may pass though the second opening 1352. The first and second leads (1316, 1331) may be affixed to the bottom surface 1342 of the substrate 1340 using adhesive. The adhesive may be integral to the conductive tape, or it may be applied to the conductive tape. A junction box 1350 may be placed over the openings (1351, 1352) and the leads (1316, 1331) to protect the module 1300 from moisture ingress. The junction box 1350 may allow for interconnection of the module 1300 to other modules and electrical devices. For example, a first wire 1351 may enter the junction box 1350 and may be joined to the first lead 1316. Similarly, a second wire 1352 may enter the junction box 1350 and may be joined to the second lead 1331. The joining may be accomplished through soldering, brazing, welding or any other suitable technique that results in a low resistance junction.

As shown in FIG. 14, a method for preparing a substrate layer for a photovoltaic module may include providing a substrate layer comprising a top surface and a bottom surface opposite the top surface 1405. The method may further include drilling a first opening extending from the top surface to the bottom surface 1410 and drilling a second opening extending from the top surface to the bottom surface 1415. The distance from a center of the first opening to a center of the second opening may be greater than about 20 mm.

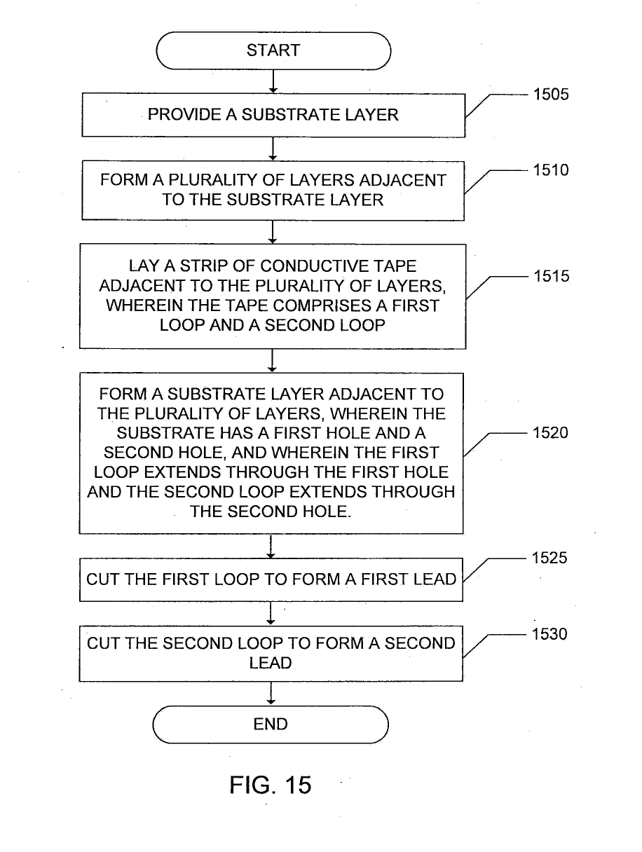

As shown in FIG. 15, a method for manufacturing a photovoltaic module may include providing a superstrate layer 1505, forming a plurality of layers adjacent to the superstrate layer 1510, and laying a strip of conductive tape adjacent to the plurality of layers where the strip of conductive tape includes a first loop and a second loop 1515. The method may further include forming a substrate layer adjacent to the plurality of layers wherein the substrate layer has a first opening and a second opening and wherein the first loop extends through the first opening and the second loop extends through the second opening 1520. The method may further include cutting the strip of conductive tape at the first loop to form a first lead 1525 and cutting the strip of conductive tape at the second loop to form a second lead 1530.

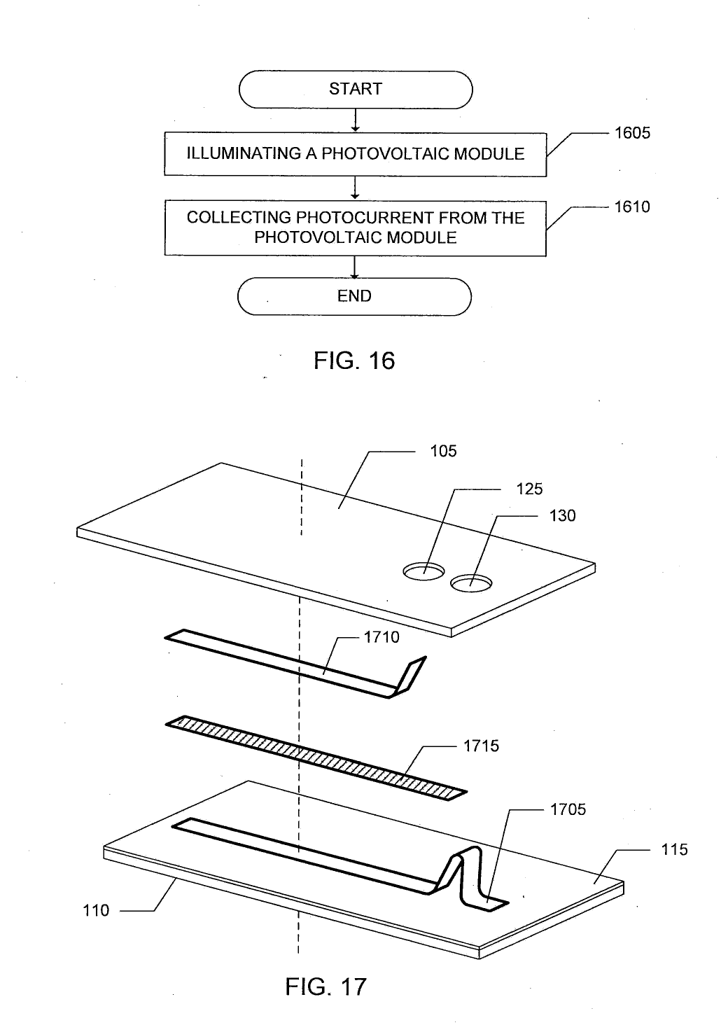

As shown in FIG. 16, a method for generating electricity may include illuminating a photovoltaic module 1605 to generate a photocurrent. The method may further include collecting the photocurrent from the photovoltaic module 1610. “Collecting” may refer to storage or using the current. For example, “collecting” may refer to storing the current in a storage device, such as a battery. Alternately, “collecting” may refer to using the current to power an electrical load.

Details of one or more embodiments are set forth in the accompanying drawings and description. Other features, objects, and advantages will be apparent from the description, drawings, and claims. Although a number of embodiments of the invention have been described, it will be understood that various modifications may be made without departing from the spirit and scope of the invention. In particular, steps depicted in figures may be executed in orders differing from the orders depicted. For example, steps may be performed concurrently or in alternate orders from those depicted. It should also be understood that the appended drawings are not necessarily to scale, presenting a somewhat simplified representation of various features and basic principles of the invention.

What is claimed is:

1. A photovoltaic module, comprising:
a substrate layer comprising:
a top surface;
a bottom surface opposite the top surface;
a first opening extending from the top surface to the bottom surface;
a second opening extending from the top surface to the bottom surface;
a plurality of layers adjacent to the substrate layer;
a first conductive tape disposed between the substrate layer and the plurality of layers, wherein the first conductive tape extends through the first opening to form a first lead; and
a second conductive tape disposed between the substrate layer and the plurality of layers, wherein the second conductive tape extends through the second opening to form a second lead.

2. The photovoltaic module of claim 1, wherein the diameter of the first opening is about 10 mm to about 40 mm, and wherein the diameter of the second opening is about 10 mm to about 40 mm.

3. The photovoltaic module of claim 1, wherein the diameter of the first opening is about 15 mm to about 25 mm, and wherein the diameter of the second opening is about 15 mm to about 25 mm.

4. The photovoltaic module of claim 1, wherein the separation distance between the first lead and the second lead is greater than or equal to about 25 mm.

5. The photovoltaic module of claim 1, wherein the openings are formed substantially centered between a first short end and a second short end of the substrate layer.

6. The photovoltaic module of claim 1, wherein the openings are formed closer to a first short end than a second short end of the substrate layer.

7. The photovoltaic module of claim 1, wherein the openings are formed substantially centered between a first long end and a second long end of the substrate layer.

8. The photovoltaic module of claim 1, wherein the openings are formed closer to a first long end than a second long end of the substrate layer.

9. The photovoltaic module of claim 1, wherein the first conductive tape is pressure-sensitive adhesive foil tape, and wherein the second conductive tape is pressure-sensitive adhesive foil tape.

10. The photovoltaic module of claim 1, wherein the plurality of layers comprises a back contact layer.

11. The photovoltaic module of claim 10, wherein the back contact layer comprises a metal.

12. The photovoltaic module of claim 1, wherein the plurality of layers comprises a semiconductor absorber layer.

13. The photovoltaic module of claim 12, wherein the absorber layer comprises a p-type semiconductor layer.

14. The photovoltaic module of claim 13, wherein the p-type semiconductor layer comprises cadmium telluride.

15. The photovoltaic module of claim 1, wherein the plurality of layers comprises a semiconductor window layer.

16. The photovoltaic module of claim 15, wherein the semiconductor window layer comprises a n-type semiconductor layer adjacent to the semiconductor absorber layer.

17. The photovoltaic module of claim 16, wherein the n-type semiconductor layer comprises cadmium sulfide.

18. The photovoltaic module of claim 1, wherein the plurality of layers comprises a transparent conductive oxide layer.

19. The photovoltaic module of claim 18, wherein the transparent conductive oxide layer comprises cadmium stannate.

20. The photovoltaic module of claim 1, further comprising a superstrate layer adjacent to the plurality of layers.

21. The photovoltaic module of claim 1, wherein the substrate layer comprises soda-lime glass.

22. A method for preparing a substrate layer for a photovoltaic module, the method comprising:
providing a substrate layer having a top surface and a bottom surface opposite the top surface;
providing a first opening extending from the top surface to the bottom surface a second opening extending from the top surface to the bottom surface,
wherein the distance from a center of the first opening to a center of the second opening is greater than about 20 mm.

23. A method for manufacturing a photovoltaic module, the method comprising:
providing a superstrate layer;
forming a plurality of layers adjacent to the superstrate layer;
laying a ship of conductive tape adjacent to the plurality of layers, wherein the strip of conductive tape comprises a first loop and a second loop;
forming a substrate layer adjacent to the plurality of layers wherein the substrate layer comprises, a top surface, a bottom surface opposite the top surface, a first opening extending from the top surface to the bottom surface, and a second opening extending from the top surface to the bottom surface, wherein the first loop extends through the first opening, and wherein the second loop extends through the second opening;
cutting the strip of conductive tape at the first loop to form a first lead; and
cutting the strip of conductive tape at the second loop to form a second lead.

24. The method of claim 23, further comprising:
attaching a junction box adjacent to the first lead and the second lead.

25. A method for generating electricity, comprising:
illuminating a photovoltaic module with light to generate photocurrent; and
collecting the photocurrent, wherein the photovoltaic module comprises:
a substrate layer, wherein the substrate comprises:
a top surface;
a bottom surface opposite the top surface;
a first opening extending from the top surface to the bottom surface, and
a second opening extending from the top surface to the bottom surface;
a plurality of layers adjacent to the substrate layer;
a first conductive tape disposed between the substrate layer and the plurality of layers, wherein the first conductive tape extends through the first opening to form a first lead; and
a second conductive tape disposed between the substrate layer and the plurality of layers, wherein the second conductive tape extends through the second opening to form a second lead.
